(19) United States
(12) Patent Application Publication
(10) Pub. No.: US 2023/0324936 A1
(43) Pub. Date: Oct. 12, 2023

(54) DIRECT CURRENT MONITORING USING A CENTRALIZED PROTECTION AND CONTROL SYSTEM

(71) Applicant: Schweitzer Engineering Laboratories, Inc., Pullman, WA (US)

(72) Inventors: Erin C. Jessup, Pullman, WA (US); Austin Edward Wade, Moscow, ID (US)

(73) Assignee: Schweitzer Engineering Laboratories, Inc., Pullman, WA (US)

(21) Appl. No.: 17/718,496

(22) Filed: Apr. 12, 2022

(51) Int. Cl. G05F 1/46; G01R 19/165

(52) U.S. Cl. CPC G05F 1/462; G01R 19/16538

(57) ABSTRACT

The present disclosure pertains to devices, systems, and methods for monitoring a direct current (DC) system. In one specific embodiment, a system may include a centralized protection and control (CPC) system. The CPC system may include a DC interface configured to be in electrical communication with a first DC system and a communication subsystem configured to receive a first measurement, from a remote device, of at least one electrical parameter of the first DC system. The CPC system may also include a DC monitor subsystem to generate a second measurement of at least one electrical parameter of the first DC system based on the electrical communication between the DC interface and the first DC system and generate a comparison of the first measurement and the second measurement. An action subsystem may generate an action based on the comparison between the first measurement and the second measurement.

### TECHNICAL FIELD

This disclosure relates to monitoring a Direct Current (DC) bus within a substation. More particularly, but not exclusively, this disclosure relates to monitoring a DC power system used to power protection equipment in a substation of an electric power system using a centralized protection and control system (CPC).

### BRIEF DESCRIPTION OF THE DRAWINGS

Non-limiting and non-exhaustive embodiments of the disclosure are described, including various embodiments of the disclosure with reference to the figures, in which:

FIG. 1A illustrates a simplified diagram of a DC distribution system consistent with embodiments of the present disclosure.

FIG. 1B illustrates a simplified diagram of a redundant DC distribution system consistent with embodiments of the present disclosure.

FIG. 2 illustrates a simplified block diagram of a CPC configured to centralize data and processing and to provide primary or backup protection for a plurality of devices in an electric power system consistent with embodiments of the present disclosure.

FIG. 3A illustrates a simplified block diagram of an electric power delivery system including a DC distribution system configured to supply DC power to a CPC and a protective relay consistent with embodiments of the present disclosure.

FIG. 3B illustrates a simplified block diagram of the electric power delivery system including two DC distribution systems to supply DC power to a CPC and a protective relay consistent with embodiments of the present disclosure.

FIG. 4 illustrates a simplified circuit diagram representing a trip circuit consistent with embodiments of the present disclosure.

FIG. 5 illustrates a flowchart of a method for monitoring a DC distribution system consistent with embodiments of the present disclosure.

### DETAILED DESCRIPTION

Electric power systems are used to generate, transmit, and distribute electric power to loads, and serve as an important part of critical infrastructure. In some cases, electric power systems and equipment may be monitored and protected by a variety of types of equipment. Such equipment may include sensors to monitor currents, voltages, phases, and other parameters of the electric power system. Relays may analyze the parameters of the electric power system to implement protective functions. The primary protective relays may communicate with various other supervisory devices such as automation systems, monitoring systems, supervisory (SCADA) systems and other intelligent electronic devices (IEDs).

Automation, protection, and monitoring equipment for electric power systems are commonly stored in substations and are powered by a direct current (DC) bus. The DC system also provides energy required to operate power system breakers. A failure of part or all of the DC distribution system causes the equipment to lose power and interrupt the function of automation, protection, and monitoring equipment. Interruption of such equipment may adversely impact the electric power system, resulting in blackouts, reduced capacity, equipment damage, or other undesirable conditions. Accordingly, maintaining power to the DC distribution systems that power such equipment is important to ensure the reliable and safe operation of associated electric power systems.

The inventors of the present disclosure have developed systems and methods to monitor DC branch circuits, including DC branch circuits in electric power system substations that provide power to power system circuit breaker trip coils, automation, protection, and monitoring equipment. In various embodiments, a centralized protection and control system (CPC) and one or more other devices may monitor electrical parameters of the system (e.g., DC voltage, Alternating Current (AC) ripple, backup battery terminal voltage, etc.). The CPC may generate a comparison of the electrical parameter it measures to the electrical parameters measured by other devices (e.g., automation, protection, and monitoring equipment, such as IEDs, protective relays, merging units, process interface units (PIU), etc. If the difference of these two signals exceeds a threshold, the system may issue an alarm or implement other actions. Such systems may quickly detect issues with the DC power supplies using high-speed communications between the remote device and the CPC.

The embodiments of the disclosure will be best understood by reference to the drawings. It will be readily understood that the components of the disclosed embodiments, as generally described and illustrated in the figures herein, could be arranged and designed in a wide variety of different configurations. Thus, the following detailed description of the embodiments of the systems and methods of the disclosure is not intended to limit the scope of the disclosure, as claimed, but is merely representative of possible embodiments of the disclosure. In addition, the steps of a method do not necessarily need to be executed in any specific order, or even sequentially, nor do the steps need to be executed only once, unless otherwise specified.

In some cases, well-known features, structures, or operations are not shown or described in detail. Furthermore, the described features, structures, or operations may be combined in any suitable manner in one or more embodiments. It will also be readily understood that the components of the embodiments, as generally described and illustrated in the figures herein, could be arranged and designed in a wide variety of different configurations. For example, throughout this specification, any reference to “one embodiment,” “an embodiment,” or “the embodiment” means that a particular feature, structure, or characteristic described in connection with that embodiment is included in at least one embodiment. Thus, the quoted phrases, or variations thereof, as recited throughout this specification are not necessarily all referring to the same embodiment.

Several aspects of the embodiments disclosed herein may be implemented as software modules or components. As used herein, a software module or component may include any type of computer instruction or computer-executable code located within a memory device that is operable in conjunction with appropriate hardware to implement the programmed instructions. A software module or component may, for instance, comprise one or more physical or logical blocks of computer instructions, which may be organized as a routine, program, object, component, data structure, etc., that performs one or more tasks or implements particular abstract data types.

In certain embodiments, a particular software module or component may comprise disparate instructions stored in different locations of a memory device, which together implement the described functionality of the module. Indeed, a module or component may comprise a single instruction or many instructions, and may be distributed over several different code segments, among different programs, and across several memory devices. Some embodiments may be practiced in a distributed computing environment where tasks are performed by a remote processing device linked through a communications network. In a distributed computing environment, software modules or components may be located in local and/or remote memory storage devices. In addition, data being tied or rendered together in a database record may be resident in the same memory device, or across several memory devices, and may be linked together in fields of a record in a database across a network.

Embodiments may be provided as a computer program product including a non-transitory machine-readable medium having stored thereon instructions that may be used to program a computer or other electronic device to perform processes described herein. The non-transitory machine-readable medium may include, but is not limited to, hard drives, floppy diskettes, optical disks, CD-ROMs, DVD-ROMs, ROMs, RAMs, EPROMs, EEPROMs, magnetic or optical cards, solid-state memory devices, or other types of media/machine-readable media suitable for storing electronic instructions. In some embodiments, the computer or another electronic device may include a processing device such as a microprocessor, microcontroller, logic circuitry, or the like. The processing device may further include one or more special purpose processing devices such as an application specific interface circuit (ASIC), PAL, PLA, PLD, field programmable gate array (FPGA), or any other customizable or programmable device.

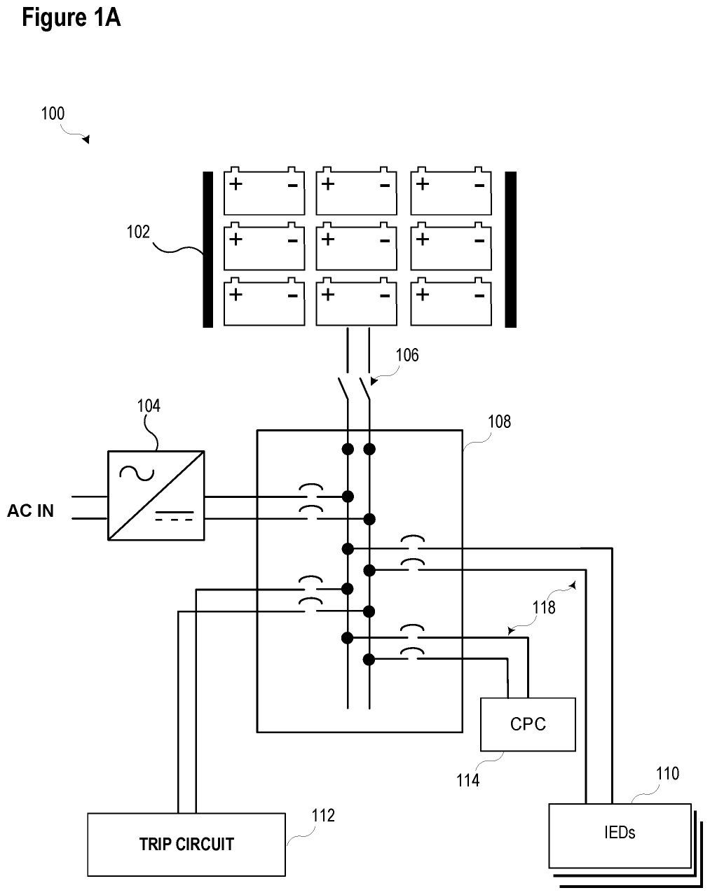

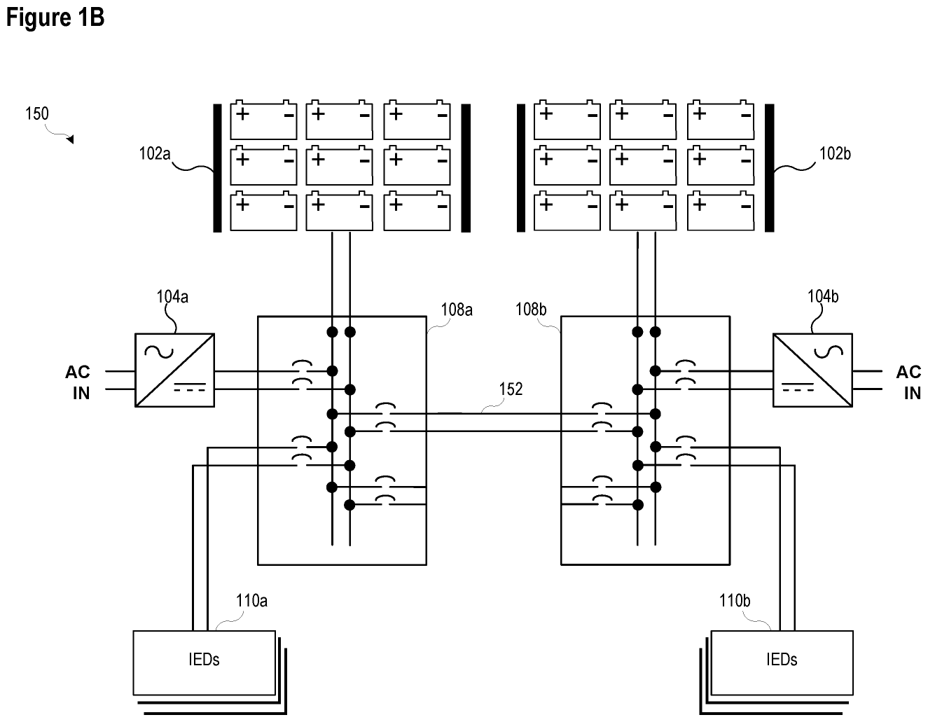

FIG. 1A illustrates a simplified diagram of a DC distribution system 100 consistent with embodiments of the present disclosure. DC distribution system 100 may receive power from an AC source (e.g., an electrical power system). An AC/DC conversion system 104 may convert an AC input to DC power suitable for use by DC distribution system 100. A battery bank 102 may provide a backup source of power in the event of a disruption in the supply of power from the AC source. A disconnect 106 may selectively enable electrical communication with battery bank 102.

A main DC panel 108 may selectively connect a plurality of branch circuits 118. One branch circuit may provide DC power to a plurality of IEDs 110. The plurality of IEDs 110 may provide monitoring, automation, and supervision of an electric power system. IEDs 110 may perform a variety of functions, such as monitoring currents and voltages within an electric power system, protecting specific equipment (e.g., generators, transformers, transmission lines, etc.), and implementing protective actions to address conditions outside of established parameters. IEDs 110 may receive information from devices that monitor conditions in the electric power system, such as merging units (MUs). MUs may be in communication with circuit breakers and may provide signals to the circuit breakers to open to selectively disconnect portions of the electric power system. IEDs 110 and MUs may also make measurements of currents, voltages, phases, and other electrical parameters that may be used to monitor, automate, and supervise the electric power system.

A CPC 114 may perform a variety of functions, including facilitating the transfer of information between IEDs 110 and providing protective functions. CPC 114 may receive redundant measurements from equipment throughout the power system and may use such information to ensure that IEDs 110 are operating as expected. In the event of unexpected operation or other issues, CPC 114 may perform the function of an affected IED. CPC 114 may utilize a variety of other redundant and/or related measurements that may also be used to evaluate the operation of other equipment. For example, CPC 114 may use redundant and/or related measurements to determine whether a contact-sensing input is reporting a correct state.

FIG. 1B illustrates a simplified diagram of a redundant DC distribution system 150 consistent with embodiments of the present disclosure. Redundant DC distribution system 150 may receive power from two AC sources (e.g., electrical power systems). AC/DC conversion systems 104a and 104b may convert the AC input to DC power suitable for use by DC distribution system 150. Battery banks 102a and 102b may provide a backup source of power in the event of a disruption in the supply of power from the AC sources.

Main DC panels 108a and 108b may selectively connect a plurality of branch circuits. The branch circuits may provide DC power to a plurality of IEDs 110a and 110b. IEDs 110a may provide monitoring, protection, and supervision for a first system, while IEDs 110b may provide monitoring, protection, and supervision for a second system.

A normally open tie 152 may connect main panels 108a and 108b. Tie 152 may be closed to allow power to transfer from main panel 108a to 108b and vice versa. Power may be transferred in various situations, including loss of AC power in electrical communication with either of AC/DC conversion systems 104a and 104b. Further, tie 152 may be closed if there are issues related to battery banks 102a and 102b.

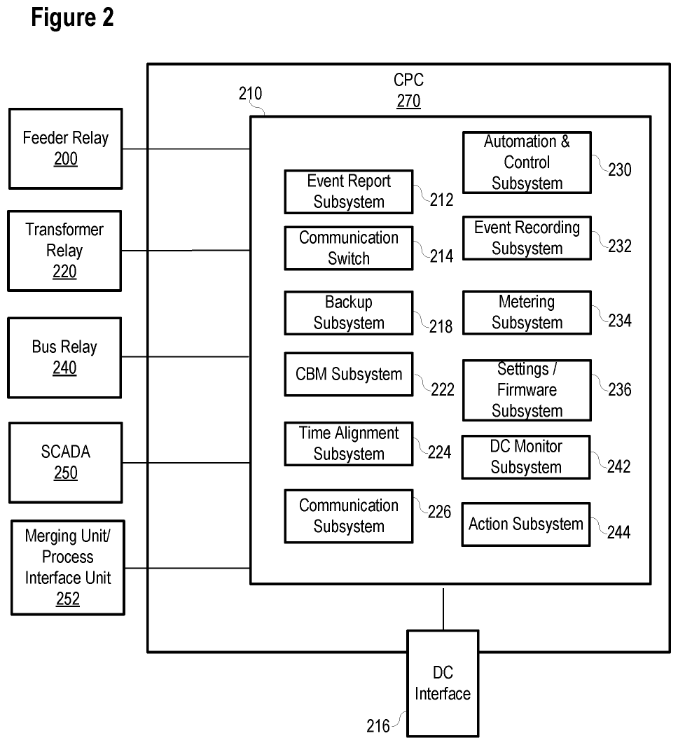

FIG. 2 illustrates a simplified block diagram of a CPC 270 configured to centralize data and processing and to provide primary or backup protection for a plurality of devices in an electric power system consistent with embodiments of the present disclosure. CPC 270 may provide automation and backup protection for the electric power system, coordinate with other CPC devices, and facilitate communication with monitoring, automation, and supervisory systems. Additionally, CPC 270 may utilize redundant information gathered from other devices to monitor one or more DC distribution systems or branch circuits within a substation.

As illustrated in FIG. 2, CPC 270 includes a processing device 210 for executing instructions related to such functions. The processing device 210 may be any processor capable of executing computer instructions including, for example, a computer processor, a microprocessor, an FPGA, or the like, and may be packaged with or be in communication with computer memory for storing computer instructions to be executed by the processing device 210. Various operations may be stored as computer instructions when executed by the processing device 210 and performed by CPC 270.

CPC 270 includes a plurality of subsystems to perform a variety of tasks. In the illustrated embodiment, CPC 270 includes a metering subsystem 234 to perform metering operations. CPC 270 may also comprise a settings/firmware subsystem 236 to adjust settings and/or firmware management operations such as: maintaining current records of settings and firmware versions for each of the connected primary relays; updating settings on primary relays; updating firmware of primary relays; and the like. An event recording subsystem 232 may record data associated with an event (e.g., detection of an equipment failure). Event recording may include power system conditions, time, and actions taken. Information recorded by event recording subsystem 232 may be analyzed by event report subsystem 212 and used to generate a report. Such a report may include, among other things, conditions associated with the event, identification of the equipment impacted by the event, etc. A backup subsystem 218 may provide backup protection for various devices, such as electrical buses, feeders, transformers, and other types of primary protective relays. Additional functions that may be performed by CPC 270 include automation and control 230. A communication switch 214 may route information among various components of CPC 270 as well as external devices in communication with CPC 270.

A time alignment subsystem 224 may align measurements, messages, and other information using a common time source. Such time alignment may allow equipment to make use of information generated by other devices. Time alignment subsystem 224 may align and/or time-stamp data received from a variety of devices (e.g., feeder relay 200, transformer relay 220, bus relay 240, DC interface 216, etc.) or data received via communication subsystem 226.

DC interface 216 may be configured to monitor electrical parameters of a DC supply, such as a DC substation bus, and to receive power from a DC supply. A DC monitor subsystem 242 may monitor a DC power source.

DC monitor subsystem 242 may monitor various electrical parameters (e.g., DC voltage, AC ripple, etc.), in the DC power received by DC interface 216 and compare the monitored electrical parameters to measurements made by a remote device. If the electrical parameters detected by DC interface 216 diverge from measurements made by the remote device, CPC 270 may issue an alert or take other action (e.g., activating a backup subsystem to power devices affected by an interruption in DC power).

A CBM subsystem 222 may receive information regarding the operation of equipment and to perform predictive analysis and to monitor the health of the equipment. The types of data analyzed may include, among other things, changes to measurements over time by redundant sources of information (e.g., for multiple CTs monitoring current through a conductor), actuation counts (e.g., for breakers or reclosers), and the like. Such information may be analyzed and used to establish trends, predict failures, and estimate the remaining life of equipment. CBM subsystem 222 may identify and detect indications of wear or degradation of equipment to enable proactive maintenance and to avoid equipment failures.

An action in response to the electrical parameters monitored by DC monitor subsystem 242 may be generated by action subsystem 244. One action that action subsystem 244 may generate is an alert. Action subsystem 244 may generate alerts in a variety of forms (e.g., messages sent via SCADA 250, e-mail notifications, SMS messages sent via cellular telephone, “push” notifications sent to a mobile or desktop application, Internet notifications, etc.). Alerts generated by action subsystem 244 may notify operators of an electric power system comprising CPC 270 of anomalous conditions or of the need for action. Action subsystem 244 may also generate commands in response to the electrical parameters monitored by DC monitor subsystem 242. For example, if the conditions indicate that power will be lost, an action may include generating a command to shut down the system.

CPC 270 may be in communication with and facilitate communication among several different devices and systems including, for example: feeder relay 200, transformer relay 220, bus relay 240, a motor relay, a generator relay, and the like. CPC 270 may be in communication with other CPCs or other types of monitoring, automation, or supervisory systems such as, for example, SCADA 250. A merging unit and process interface unit (PIU) may enable communication between CPC 270 and a MU or a PIU. A MU may provide measurements of various signals (e.g., voltage measurements, current measurements, binary statuses, raw analog signals, etc.). A PIU may provide the function of a merging unit along with the function of a remote I/O module (RIO). An RIO may be an interface for equipment such as circuit breakers, transformers, isolators, etc. CPC 270 may perform a variety of other communication functions and may function as a communication switch among the various connected devices.

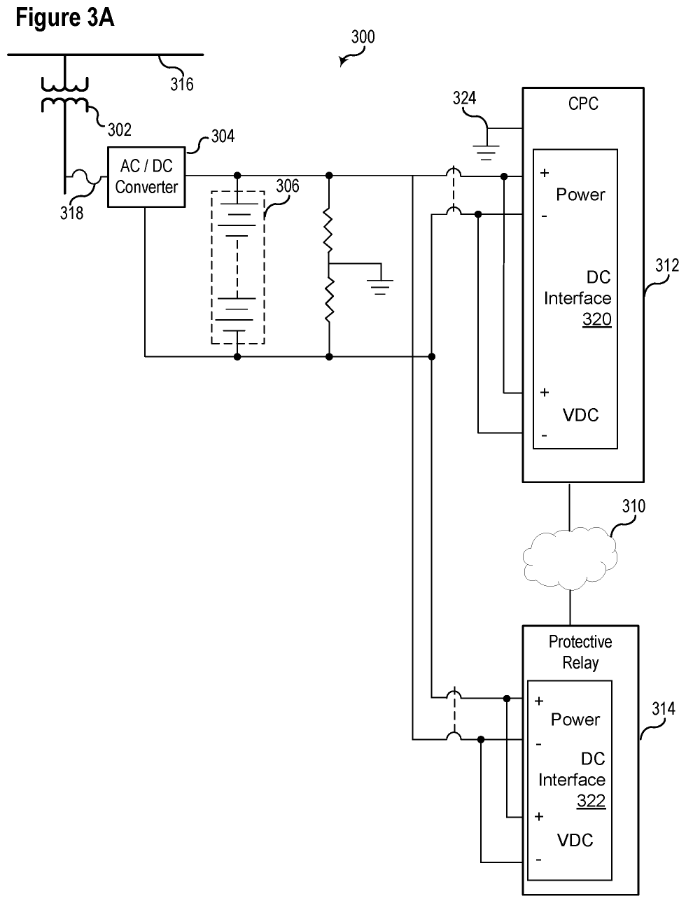

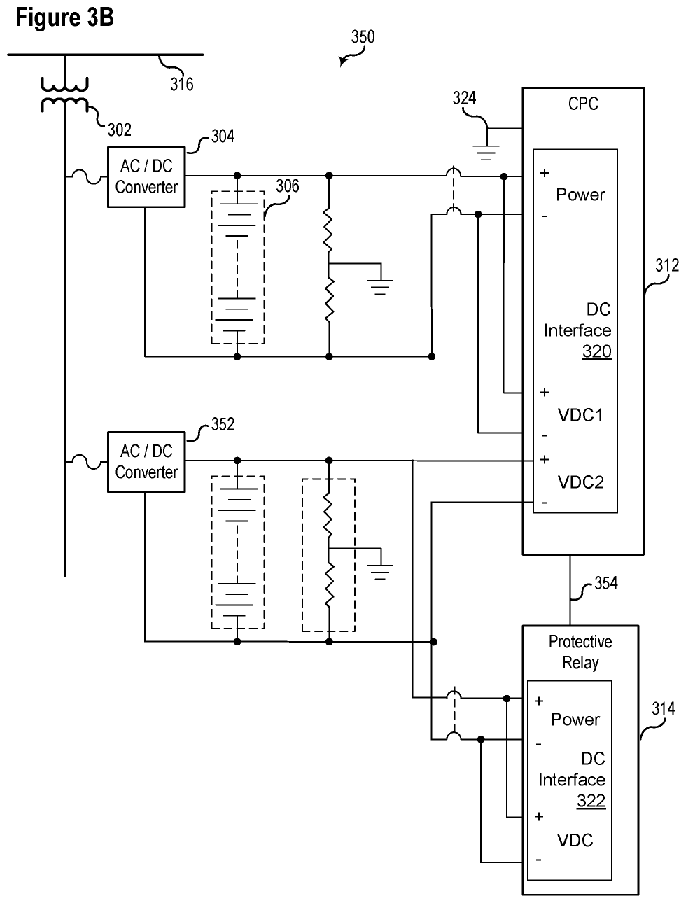

FIG. 3A illustrates a simplified block diagram of system 300 including a DC distribution system configured to supply DC power to a CPC 312 and a protective relay 314 consistent with embodiments of the present disclosure. A transformer 302 may step down energy from a voltage of an AC electrical bus 316. In other embodiments, a MU, an intelligent MU, a PIU, protective relay, or an IED. A fuse 318 may connect the low-voltage side of transformer 302 to an AC/DC converter 304, which may convert the stepped-down voltage AC energy to DC energy. An equipment ground 324 may be provided. In one specific embodiment, AC/DC converter 304 may create a 125 VDC output.

AC/DC converter 304 may charge a battery 306. The battery 306 may provide power to CPC 312 and protective relay 314 in the event of a loss of power delivered by AC electrical bus 316, operation of the fuse 318, or failure of AC/DC converter 304.

CPC 312 and protective relay 314 may each include a DC interface, 320 and 322, respectively. DC interfaces 320 and 322 may each include a first set of terminals to receive DC power and a second set of terminals that may be used to monitor electrical parameters associated with the DC power supply. In other embodiments, a single set of terminals may be used to receive power and to monitor electrical parameters. DC interface 320 and DC interface 322 may each monitor various parameters (e.g., DC voltage, AC ripple, battery 306 terminal voltage, etc.). Information about the electrical parameters of the DC power supply may be communicated between CPC 312 and protective relay 314 via a data connection 310. Data connection 310 may comprise a network or may be a direct connection. Differences in the measurements between the electrical parameters of the DC power supply measured by CPC 312 and protective relay 314 may be used to establish criteria for setting an alarm or implementing an action.

FIG. 3B illustrates a simplified block diagram of system 350 including two DC distribution systems to supply DC power to a CPC 312 and a protective relay 314 consistent with embodiments of the present disclosure. A first DC distribution system powered by AC/DC converter 304 may provide DC power to CPC 312, while a second DC distribution system powered by AC/DC converter 352 may provide power to protective relay 314. CPC 312 may also include a third set of terminals to monitor the electrical power provided by the second DC distribution system.

Protective relay 314 receives power from the second DC distribution system and may monitor electrical parameters associated with the second DC distribution system. The electrical parameters measured by protective relay 314 may be communicated to CPC 312 through a data connection 354. CPC 312 may determine if the electrical parameters measured by protective relay 314 and associated with the second DC distribution system deviate from the parameters measured by CPC 312. If a deviation is detected, an alert or an action may be triggered. In one specific embodiment, CPC 312 may include a comparator to generate a comparison between the remote measured quantity from the locally measured quantity and to detect any divergence. If the output of the comparator exceeds a threshold, an alert or action may be triggered.

The concepts described in FIGS. 3A and 3B may be extended to include additional DC distribution systems, where devices communicate measurements of electrical parameters associated with a DC distribution system to a CPC. Such a system may detect failures and may generate alerts or actions based on detection of out-of-tolerance DC power conditions.

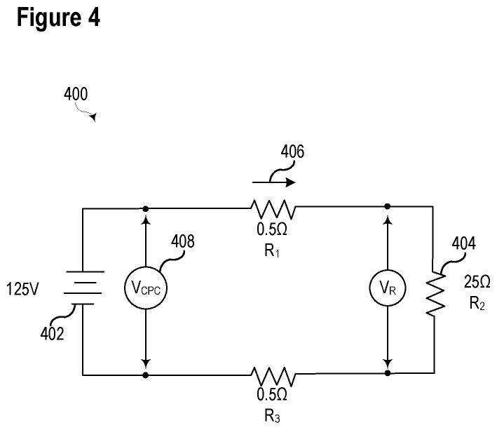

FIG. 4 illustrates a simplified circuit diagram 400 representing a trip circuit consistent with embodiments of the present disclosure. A trip coil may be represented as a resistor 404 connected to a battery 402. A trip current 406 may be measured by a remote device (e.g., a protective relay, an intelligent merging unit, etc.). During a trip event, the remote device may measure the supplied voltage 408 (V_{CPC}) and the trip current 406. These measurements may be communicated to a CPC (not shown).

The trip current 406 can be used as the approximate current through a relay branch circuit. The CPC can determine the difference in the voltages and calculate a branch circuit resistance using values received from the remote device. This resistance can be characterized during the commissioning process and stored by the CPC. An alarm or action may be triggered if the branch circuit resistance rises in the future. Such an approach may identify various issues (e.g., corrosion on terminals or damaged branch circuit conductors).

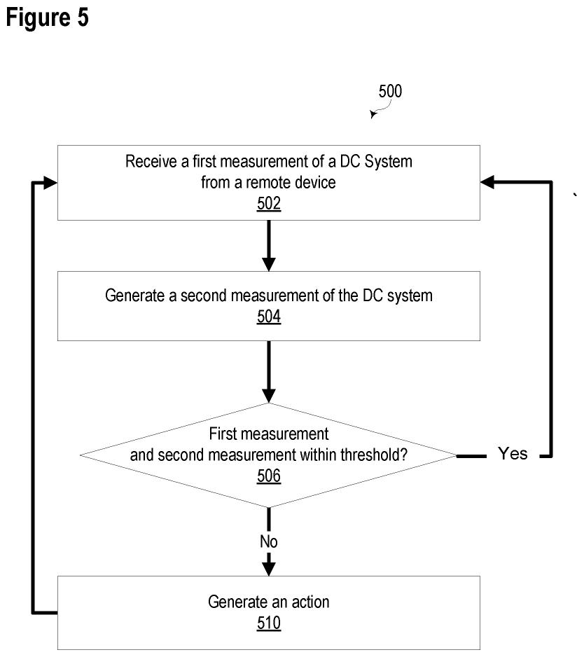

FIG. 5 illustrates a flowchart of a method 500 for monitoring a DC distribution system consistent with embodiments of the present disclosure. At 502, a device implementing method 500 may receive a first measurement of a DC system from a remote device. In various embodiments, the device implementing method 500 may be a CPC in an electric power system.

At 504, a second measurement of the DC system may be generated. The second measurement may be generated by a device implementing method 500. In some embodiments, the device may draw power from the DC system being monitored. In such embodiments, one set of terminals in electrical communication with the DC system may be used to receive electrical power and the other set of terminals may be used to generate measurements associated with the DC system.

At 506, method 500 may determine whether the first measurement and the second measurement are within a threshold. For example, the first measurement may be compared to the second measurement using a comparator. Any difference between the first measurement and the second measurement may be compared to a threshold. If the difference is less than the threshold, method 500 may return to 502.

If the first measurement and the second measurement are outside of the threshold, an action may be generated at 510. The action may include an alert sent to an operator. Further, control actions may be generated based on the first measurement and the second measurement being outside of the threshold.

While specific embodiments and applications of the disclosure have been illustrated and described, it is to be understood that the disclosure is not limited to the precise configurations and components disclosed herein. Accordingly, many changes may be made to the details of the above-described embodiments without departing from the underlying principles of this disclosure. The scope of the present invention should, therefore, be determined only by the following claims.

What is claimed is:

1. A system to monitor at least one direct current (DC) system, comprising:
a centralized protection and control (CPC) system, comprising:
a DC interface configured to be in electrical communication with a first DC system;
a communication subsystem configured to receive a first measurement from a remote device of at least one electrical parameter of the first DC system;
a DC monitor subsystem configured to:
generate a second measurement of the at least one electrical parameter of the first DC system based on the electrical communication between the DC interface and the first DC system; and
generate a comparison of the first measurement and the second measurement; and
an action subsystem configured to generate an action based on the comparison between the first measurement and the second measurement.

2. The system of claim 1, wherein the first DC system comprises a DC distribution system in an electric power system.

3. The system of claim 1, wherein the first DC system comprises a battery.

4. The system of claim 1, wherein the remote device comprises one of a protective relay in an electric power system.

5. The system of claim 1, wherein the remote device comprises a merging unit in an electric power system.

6. The system of claim 1, wherein the remote device comprises an intelligent electronic device in an electric power system.

7. The system of claim 1, wherein the action comprises an alert to be transmitted to an operator.

8. The system of claim 1, wherein the action comprises one of a protective action and a control action.

9. The system of claim 1, wherein the DC interface comprises a plurality of terminals.

10. The system of claim 9, wherein the plurality of terminals comprises:
a first set of terminals to receive electrical power for the CPC system; and
a second set of terminals in electrical communication with the DC monitor subsystem and configured to be in electrical communication with the first DC system;
wherein the DC monitor subsystem is further configured to generate the second measurement based on an electrical parameter associated with the second set of terminals.

11. The system of claim 10, wherein the plurality of terminals comprises:
a third set of terminals in electrical communication with the DC monitor subsystem and configured to be in electrical communication with a second DC subsystem;
wherein the DC monitor subsystem is further configured to generate a third measurement based on an electrical parameter associated with the third set of terminals.

12. The system of claim 1, wherein the at least one electrical parameter of the DC monitor subsystem comprises one of a DC voltage, an alternating current ripple, and a battery terminal voltage.

13. The system of claim 1, wherein:
the first measurement comprises a trip coil current;
the DC monitor subsystem is further configured to determine a branch circuit resistance based on the trip coil current and compare the branch circuit resistance to a stored value; and
the action subsystem is further configured to generate a second action based on a difference between the branch circuit resistance and the stored value.

14. A method of monitoring at least one direct current (DC) system, comprising:
placing a centralized protection and control (CPC) system comprising a DC interface in electrical communication with a first DC system;
receiving, using a communication subsystem of the CPC, a first measurement, from a remote device, of at least one electrical parameter of the first DC system;
generating, using a DC monitor subsystem of the CPC, a second measurement of at least one electrical parameter of the first DC system based on the electrical communication between the DC interface and the first DC system;
generating, using the DC monitor subsystem, a comparison of the first measurement and the second measurement; and
generating, using an action subsystem, an action based on the comparison between the first measurement and the second measurement.

15. The method of claim 14, wherein the first DC system comprises a DC distribution system in an electric power system.

16. The method of claim 14, wherein the first DC system comprises a battery.

17. The method of claim 14, wherein the remote device comprises a protective relay in an electric power system.

18. The method of claim 14, wherein the remote device comprises a merging unit in an electric power system.

19. The method of claim 14, wherein the remote device comprises an intelligent electronic device in an electric power system.

20. The method of claim 14, wherein the action comprises an alert to be transmitted to an operator.

21. The method of claim 14, wherein the action comprises one of a protective action and a control action.

22. The method of claim 14, wherein the DC interface comprises a plurality of terminals.

23. The method of claim 22, further comprising:
connecting a first set of terminals to receive electrical power for the CPC system;
connecting a second set of terminals to the DC monitor subsystem; and
generating, using the DC monitor subsystem, the second measurement based on an electrical parameter associated with the second set of terminals.

24. The method of claim 23, further comprising:
connecting a third set of terminals in electrical communication with the DC monitor subsystem and configured to be in electrical communication with a second DC subsystem; and
generating, using the DC monitor subsystem, a third measurement based on an electrical parameter associated with the third set of terminals.

25. The method of claim 14, wherein the at least one electrical parameter of the DC monitor subsystem comprises one of a DC voltage, an alternating current ripple, and a battery terminal voltage.

26. The method of claim 14, further comprising:
determining, using the DC monitor subsystem, a branch circuit resistance based on a trip coil current;
comparing, using the DC monitor subsystem, the branch circuit resistance to a stored value; and
generating, using the action subsystem, a second action based on a difference between the branch circuit resistance and the stored value.
